(19) United States
(12) Patent Application Publication
(10) Pub. No.: US 2008/0317967 A1
(43) Pub. Date: Dec. 25, 2008

(54) Deposition of Polymeric Films

(76) Inventors: Kwang-Leong Choy, Nottingham (GB); Xianghui Hou, Nottingham (GB)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 11/816,178

(22) PCT Filed: Feb. 14, 2006
(86) PCT No.: PCT/GB06/00511

§ 371 Date: Aug. 19, 2008

(30) Foreign Application Priority Data
Feb. 14, 2005 (GB) 0503029.1
Jul. 15, 2005 (GB) 0514576.8

(51) Int. Cl. B05D 1/06; B05B 5/025; C23C 16/46; B05D 1/04

(52) U.S. Cl. 427/485; 118/621; 427/458; 118/715

(57) ABSTRACT

An apparatus for and method of depositing a polymeric film on a substrate (5), the apparatus comprising: a delivery unit (7, 8) for delivering an aerosol spray comprising aerosol droplets of a liquid precursor comprising a polymeric phase to the substrate, the polymeric phase comprising a polymeric material and at least one solvent; a heating unit (15) for at least heating an environment such as at least partially to evaporate the at least one solvent of the polymeric phase prior to the aerosol droplets depositing on the substrate; and an electrostatic field generation unit (9) for generating an electrostatic field between the delivery unit and the substrate, and electrostatically charging the aerosol droplets such that the aerosol droplets are electrostatically attracted to the substrate.

The present invention relates to an apparatus for and method of depositing polymeric films, in particular thin and super-thin polymeric films.

Super-thin polymeric films have received increasing interest in recent years for a wide range of applications in engineering sectors and consumer products. These include protective films, as lubricants, in printing, and in biomedical and electronic components.

There is a need to fabricate super-thin polymeric films with well-controlled chemical composition, surface morphology, uniformity and thickness. There are various processing methods to produce thin polymeric films, such as casting, spinning, dipping, spraying, electrospray and self-assembly. However, a rapid and well-controlled method has yet to be established.

It is an aim of the present invention to provide an apparatus for and method of depositing polymeric films, in particular thin and super-thin polymeric films.

In one aspect the present invention provides an apparatus for depositing a polymeric film on a substrate, the apparatus comprising: a delivery unit for delivering an aerosol spray comprising aerosol droplets of a liquid precursor comprising a polymeric phase to the substrate, the polymeric phase comprising a polymeric material and at least one solvent; and an electrostatic field generation unit for generating an electrostatic field between the delivery unit and the substrate, and electrostatically charging the aerosol droplets such that the aerosol droplets are electrostatically attracted to the substrate.

In one embodiment the apparatus further comprises: a heating unit for at least heating an environment such as at least partially to evaporate the at least one solvent of the polymeric phase prior to the aerosol droplets depositing on the substrate.

In another aspect the present invention provides a method of depositing a polymeric film on a substrate, the method comprising the steps of: delivering an aerosol spray comprising aerosol droplets of a liquid precursor comprising a polymeric phase to the substrate, the polymeric phase comprising a polymeric material and at least one solvent; and generating an electrostatic field towards the substrate, and electrostatically charging the aerosol droplets such that the aerosol droplets are electrostatically attracted to the substrate.

In one embodiment the method further comprises the step of: heating at least an environment such as at least partially to evaporate the at least one solvent of the polymeric phase prior to the aerosol droplets depositing on the substrate.

The present invention is particularly advantageous in enabling the fabrication of films with good thickness control, uniformity and morphology, and in some embodiments avoids the need for environmental control, such as the use of a vacuum.

The present invention extends to the deposition of polymeric films by aerosol-assisted ion deposition, with or without subsequent heat treatment.

The novel process is flexible and can produce single-layer, multi-layer, compositionally-graded, doped, hybrid or nanocomposite films, as either dense or porous films.

The films can be single-phase or multi-phase films, where containing, for example, polymeric, metallic, ceramic, fluorescent and/or other natural or synthetic components, for example, dyes and essential oils.

The films can be single-function films, or alternatively can be multi-function or smart-function films, as achieved by incorporating additional materials that provide such functions.

Examples of films which can be fabricated by the present invention are composite films, including nanocomposite films, which consist, for example, of a ceramic, metallic, inorganic, organic, organic/inorganic hybrid and/or polymeric reinforcement in a polymeric matrix.

Preferred embodiments of the present invention will now be described hereinbelow by way of example only with reference to the accompanying drawings, in which:

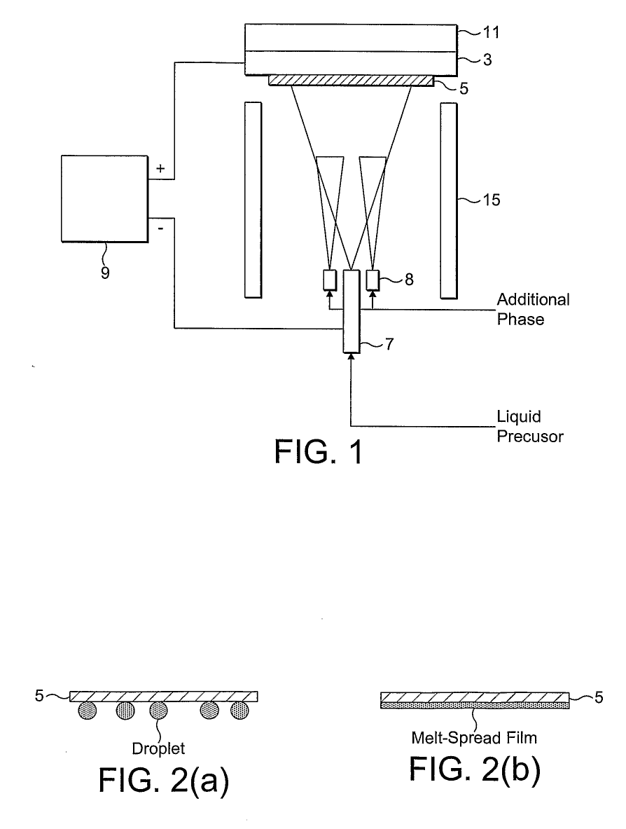

FIG. 1 schematically illustrates a deposition apparatus in accordance with a first embodiment of the present invention;

FIGS. 2(a) and (b) schematically represent the melt-spreading of droplets as deposited by the apparatus of FIG. 1 in the fabrication of a thin polymeric film;

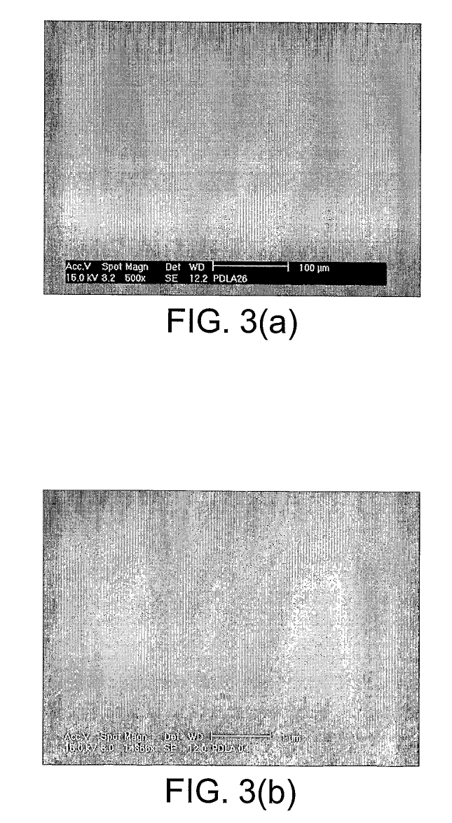

FIGS. 3(a) and (b) illustrate SEM micrographs of a PDLLA film in accordance with Example #1 as deposited by the apparatus of FIG. 1;

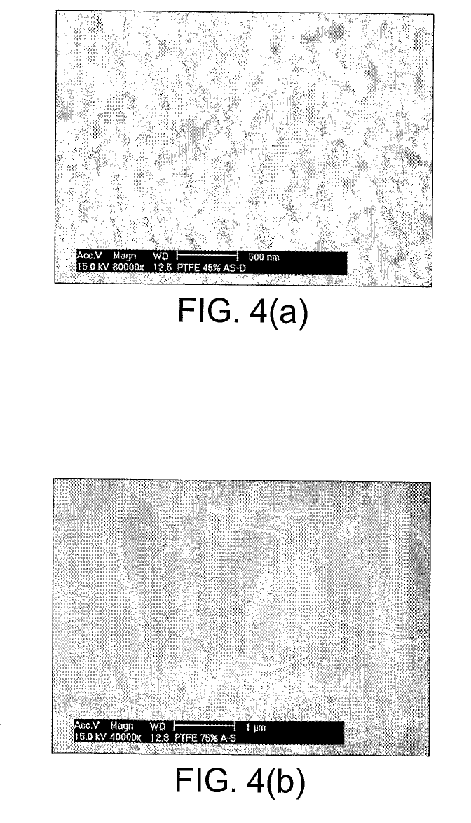

FIGS. 4(a) and (b) illustrate SEM micrographs of a PTFE film in accordance with Example #2 as deposited by the apparatus of FIG. 1 and subsequent to heat treatment, respectively; and

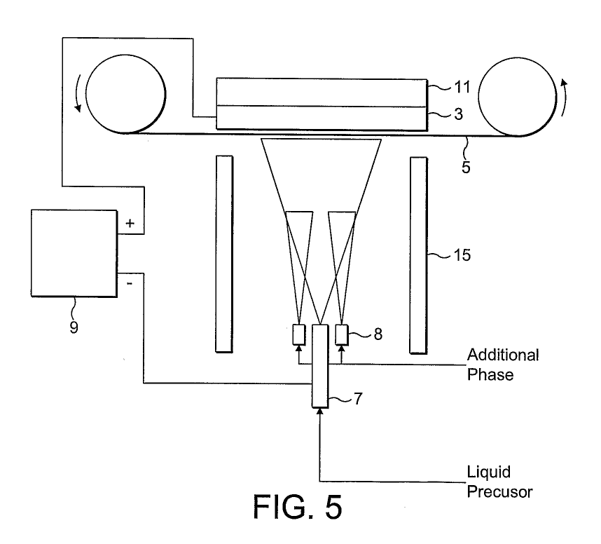

FIG. 5 schematically illustrates a deposition apparatus in accordance with a second embodiment of the present invention.

FIG. 1 illustrates a deposition apparatus in accordance with a first embodiment of the present invention.

The deposition apparatus comprises a substrate holder 3 for holding a substrate 5, in this embodiment stationary, onto which a thin polymeric film is to be deposited.

In this embodiment the substrate holder 3 is configured such that the substrate 5 faces vertically downwardly.

In other embodiments the substrate holder 3 can be configured to hold the substrate 5 in any orient, for example, facing vertically upwardly, facing horizontally of at any inclined angle.

In this embodiment the substrate 5 is conductive, but in another embodiment can be non-conductive.

The deposition apparatus further comprises a first delivery unit 7, in this embodiment an aerosol generator for generating an aerosol spray of a liquid precursor.

In this embodiment the liquid precursor comprises a polymeric phase, which is one of a polymeric solution, colloid or suspension, which contains a solvent, which can comprise one or both of an organic or inorganic solvent. Polymeric materials include PLLDA and PTFE.

In one embodiment the liquid precursor can contain at least one additional phase.

In one alternative embodiment, as in this embodiment, and as will be described in detail hereinbelow, at least one additional phase can be introduced separately into the stream of aerosol droplets as generated by the first delivery unit 7, such that the polymeric and additional phases are together deposited on the surface of the substrate 5.

In another alternative embodiment, at least one additional phase can be delivered directly to the surface of the substrate 5, such that the polymeric and additional phases are together deposited on the surface of the substrate 5.

The at least one additional phase can be a structural or a functional phase.

The at least one additional phase can be delivered as one or more of a solid, liquid or gaseous phase.

In one embodiment the at least one additional phase can comprise a polymeric material, a metallic material, a ceramic material, a glass material or a carbon material.

In one embodiment the at least one additional phase is delivered in solid form, in particular as particulates, fibers or tubes, in particular ultrafine structures, and especially nanostructures, such as nanoparticles, nanofibers and nanotubes, having a size of from about 1 nm to about 100 nm, and sub-nanostructures having a size of less than about 1 nm.

In one embodiment the at least one additional phase can comprise inorganic structures, in particular inorganic filaments.

In another embodiment the at least one additional phase can comprise organic structures, in particular organic filaments.

In another embodiment, where the at least one additional phase is delivered as a liquid or a gas, the liquid or gas transforms to provide a solid phase, for example, by way of reaction with the host, polymeric phase.

In one embodiment the at least one additional phase acts as a re-inforcement to the host, polymeric phase.

In one embodiment the at least one additional phase can comprise a coloring material, for example, a dye, a fluorescent material, and a cosmetic material, for example, essential oils, where in natural or synthetic form.

In this embodiment the first delivery unit 7 is configured such as to generate a super-fine aerosol comprising nanometer-sized droplets, such as to allow for the generation of thin films, typically having a thickness of from about 10 nm to about 10 μm.

The thickness of the deposited film is in part determined by the time of deposition, and depending on the thickness of the film required, the outlet of the first delivery unit 7 can be moved relative to the substrate 5, such as to form thicker films by layer-by-layer deposition. Three-dimensional structures can also be fabricated in this way.

In one embodiment localized deposition can be achieved by targeting the stream of aerosol droplets at one or more specific regions of the substrate 5.

In this embodiment the solvent is carefully selected such as to provide the required evaporation behavior, and the generated aerosol droplets have a narrow particle size distribution, such as to minimize the variation in evaporation as caused by effects of surface area.

The deposition apparatus further comprises a second delivery unit 8 for delivering the at least one additional phase, in this embodiment into the stream of aerosol droplets of the host, polymeric phase as generated by the first delivery unit 7. In an alternative embodiment the second delivery unit 8 can be configured to deliver the at least one additional phase directly to the surface of the substrate 5.

In this embodiment the second delivery unit 8 comprises an aerosol generator for generating an aerosol, in one embodiment a super-fine aerosol comprising the at least one additional phase.

In this embodiment the second delivery unit 8 is disposed co-axially about the first delivery unit 7, such that the at least one additional phase as delivered by the second delivery unit 8 is entrained in the stream of aerosol droplets as generated by the first delivery unit 7, but can be disposed in any configuration, such as remotely from the first delivery unit 7, such that the at least one additional phase is delivered directly to the surface of the substrate 5.

The deposition apparatus further comprises a voltage supply 9 for applying an electrical voltage between the outlet of the first delivery unit 7 and the substrate holder 3, such as oppositely to charge the droplets of the aerosol as generated by the first delivery unit 7 and the substrate holder 3, whereby an electrostatic field is generated between the first delivery unit 7 and the substrate 5 and the aerosol droplets are attracted to the exposed surface of the substrate 5. As the aerosol droplets deposit on the exposed surface of the substrate 5, the deposited droplets act to cause subsequent droplets to be preferentially directed to the regions of the substrate 5 which are still exposed and have the minimum density of deposited droplets. In this way, a thin film of uniform thickness is rapidly achieved.

The deposition apparatus further comprises a first, substrate heater 11, which in this embodiment is disposed to the rear of the substrate holder 3 and acts to heat the substrate 5, such that the substrate 5 can be maintained at an elevated temperature. The temperature of the substrate 5 can be maintained at any temperature from room temperature to a temperature above the melting point of the polymeric material.

In an alternative embodiment the substrate 5 can be pre-heated.

Where the substrate 5 is at a temperature above the melting point of the polymeric material, the polymeric film is formed in situ by melt spreading. In an alternative embodiment the substrate 5 can be at a temperature below the melting point of the polymeric material during deposition and subsequently heat treated. FIGS. 2(a) and (b) illustrate the droplet deposition and melt-spreading mechanism of the present invention.

The deposition apparatus further comprises a second, environment heater 15 for heating at least the environment between the outlet of the first delivery unit 7 and the substrate 5, such as at least partially to evaporate the solvent of the liquid precursor.

In this embodiment the heaters 11, 15 can be any of UV, plasma, resistive or inductive heaters.

In one embodiment the environment is maintained at a temperature which is such that the aerosol droplets are semi-dried prior to reaching the surface of the substrate 5, in which condition substantially all of the solvent has been evaporated.

In another embodiment the environment is maintained at a temperature which is such that the aerosol droplets are fully dried prior to reaching the surface of the substrate 5.

In one embodiment the environment is maintained at a temperature which is such that the polymeric material of the droplets is semi-melted, which allows for some spreading on impact of the droplets onto the surface of the substrate 5.

In another embodiment the environment is maintained at a temperature which is such that the droplets are molten, which allows for significant spreading on impact of the droplets onto the surface of the substrate 5.

Typically, the temperature is maintained at a temperature from room temperature to about 300° C.

In this embodiment the deposition apparatus is in an open environment.

In another embodiment the deposition apparatus can be contained in a closed chamber, such as to allow for operation in a controlled environment, for example, in an inert gas.

In one embodiment the environment is maintained at atmospheric pressure.

In another embodiment the atmosphere can be maintained at a reduced or increased pressure relative to atmospheric pressure.

The present invention will now be described hereinbelow by way of example only with reference to the following non-limiting Examples.

### EXAMPLE #1

### Deposition of poly(D,L-lactic Acid) Films

In this Example, highly-uniform and smooth poly (D,L-lactic acid) films were obtained, as illustrated in FIGS. 3(a) and (b).

| PDLLA films | Examples of range of processing conditions |
|---|---|
| Solution concentration | 0.001-20 wt % |
| Solvent | Organic solvent |
| Substrate | 20-230 ° C., preferably 50-200 ° C. |
| temperature | |
| Aerosol flow rate | 0.01-50 ml/hour, preferably 1-15 ml/hour |
| Stand-off distance* | 10-80 mm, preferably 10-50 mm |
| Applied voltage | 100 V-20 kV, preferably 4-12 kV |

*distance between the first delivery unit 7 and the substrate 5

### EXAMPLE #2

### Deposition of Polytetrafluoroethylene (PTFE) Films

In this Example, polytetrafluoroethylene (PTFE) films were obtained both directly without further heat-treatment and indirectly with further heat-treatment, FIGS. 4(a) and (b) show SEM micrographs respectively following droplet deposition and following subsequent heat treatment.

| PTFE films | Examples of range of processing conditions |
|---|---|
| Solution concentration | 0.001-10 wt % |
| Solvent | Alcohol:Water = (50~100):(50~0) |
| Substrate | 20-250° C., preferably 70-180° C. |
| temperature | |
| Aerosol flow rate | 0.01-50 ml/hour, preferably 1-18 ml/hour |
| Stand-off distance* | 10-80 mm, preferably 10-60 mm |
| Applied voltage | 100 V-20 kV, preferably 4-12 kV |

*distance between the first delivery unit 7 and the substrate 5

FIG. 5 illustrates a deposition apparatus in accordance with a second embodiment of the present invention.

The deposition apparatus of this embodiment is quite similar to the deposition apparatus of the above-described first embodiment, and thus, in order to avoid any unnecessary duplication of description, only the differences will be described in detail, with like reference signs designating like parts.

The deposition apparatus of this embodiment differs from that of the above-described first embodiment in that the substrate 5 is moved relative to the first delivery unit 7, in this embodiment advanced in front of the first delivery unit 7. In preferred embodiments the substrate 5 comprises a sheet, such as a metal or a plastics sheet, or a fiber, such as an optical fiber.

Finally, it will be understood that the present invention has been described in its preferred embodiments and can be modified in many different ways without departing from the scope of the invention as defined by the appended claims.

For example, in one modification, the deposition apparatus can include a focused heating unit, such as a laser, for selectively heating regions of the surface of the substrate 5, and thereby enabling the patterning of the film as deposited on the substrate 5.

1. An apparatus for depositing a polymeric film on a substrate, the apparatus comprising:
a delivery unit for delivering an aerosol spray comprising aerosol droplets of a liquid precursor comprising a polymeric phase to the substrate, the polymeric phase comprising a polymeric material and at least one solvent;
a heating unit for at least heating an environment such as at least partially to evaporate the at least one solvent of the polymeric phase prior to the aerosol droplets depositing on the substrate; and
an electrostatic field generation unit for generating an electrostatic field between the delivery unit and the substrate, and electrostatically charging the aerosol droplets such that the aerosol droplets are electrostatically attracted to the substrate.

2. The apparatus of claim 1, wherein the substrate is stationary.

3. The apparatus of claim 1, wherein the substrate is moved relative to the delivery unit.

4. The apparatus of claim 3, wherein the substrate is advanced in front of the delivery unit.

5. The apparatus of claim 4, wherein the substrate comprises one of a fiber or a sheet.

6. The apparatus of claim 1, wherein the substrate is conductive.

7. The apparatus of claim 1, wherein the substrate is non-conductive.

8. The apparatus of claim 1, wherein the delivery unit is configured such as to direct the aerosol spray upwardly.

9. The apparatus of claim 1, wherein the delivery unit comprises at least one aerosol generator.

10. The apparatus of claim 1, wherein the polymeric phase comprises a polymeric solution.

11. The apparatus of claim 1, wherein the polymeric phase comprises a polymeric colloid.

12. The apparatus of claim 1, wherein the polymeric phase comprises a polymeric suspension.

13. The apparatus of claim 1, wherein the liquid precursor further comprises at least one additional phase.

14. The apparatus of claim 1, further comprising:
a further delivery unit for delivering at least one additional phase into the aerosol spray of the liquid precursor as delivered by the one delivery unit.

15. The apparatus of claim 1, further comprising:
a further delivery unit for delivering at least one additional phase to the substrate.

16. The apparatus of claim 14, wherein the further delivery unit comprises an aerosol generator.

17. The apparatus of claim 14, wherein the delivery units are disposed in co-axial relation.

18. The apparatus of claim 13, wherein the additional phase comprises a solid phase, preferably the solid phase comprises at least one of particles, fibers or tubes, more preferably the solid phase comprises nanostructures, and even more preferably the solid phase comprises sub-nanostructures.

19. (canceled)

20. (canceled)

21. (canceled)

22. The apparatus of claim 13, wherein the additional phase is delivered as a liquid phase, and preferably such as to transform to a solid phase.

23. The apparatus of claim 13, wherein the additional phase is delivered as a gas phase, and preferably such as to transform to a solid phase.

24. (canceled)

25. The apparatus of claim 13, wherein the additional phase comprises at least one of a polymeric material, a metallic material, a ceramic material, a glass material and a carbon material.

26. The apparatus of claim 13, wherein, in the polymeric film, the additional phase is present as a re-inforcement to the polymeric phase.

27. The apparatus of claim 13, wherein the additional phase comprises one or both of a coloring or fluorescent material.

28. The apparatus of claim 13, wherein the additional phase comprises a cosmetic material, and preferably the cosmetic material comprises one or more essential oils.

29. (canceled)

30. The apparatus of claim 1, wherein the heating unit is operative to heat the environment such as substantially completely to evaporate the at least one solvent of the polymeric phase prior to the aerosol droplets depositing on the substrate.

31. The apparatus of claim 1, wherein the heating unit is operative to heat the environment to a temperature which is such as at least partially to melt the polymeric material in the aerosol droplets.

32. The apparatus of claim 31, wherein the heating unit is operative to heat the environment to a temperature which is such that the polymeric material in the aerosol droplets is molten.

33. The apparatus of claim 1, further comprising:
a further heating unit for heating the substrate.

34. The apparatus of claim 1, wherein the substrate is pre-heated.

35. The apparatus of claim 33, wherein the substrate is heated to a temperature below the melting point of the polymeric material in the aerosol droplets.

36. The apparatus of claim 33, wherein the substrate is heated to a temperature above the melting point of the polymeric material in the aerosol droplets, such that a polymeric film is obtained by melt spreading.

37. The apparatus of claim 1, wherein the polymeric film has a thickness of less than about 10 μm.

38. The apparatus of claim 37, wherein the polymeric film has a thickness of less than about 100 nm.

39. The apparatus of claim 1, further comprising:
a further electrostatic field generation unit for generating an electrostatic field laterally relative to the substrate, such as electrostatically to guide the aerosol droplets to a surface of the substrate.

40. A method of depositing a polymeric film on a substrate, the method comprising the steps of:
delivering an aerosol spray comprising aerosol droplets of a liquid precursor comprising a polymeric phase to the substrate, the polymeric phase comprising a polymeric material and at least one solvent;
heating at least an environment such as at least partially to evaporate the at least one solvent of the polymeric phase prior to the aerosol droplets depositing on the substrate; and
generating an electrostatic field towards the substrate, and electrostatically charging the aerosol droplets such that the aerosol droplets are electrostatically attracted to the substrate.

41. The method of claim 40, wherein the substrate is stationary.

42. The method of claim 40, wherein the substrate is moved relative to the delivery unit.

43. The method of claim 42, wherein the substrate is advanced in front of the delivery unit.

44. The method of claim 43, wherein the substrate comprises one of a fiber or a sheet.

45. The method of claim 40, wherein the substrate is conductive.

46. The method of claim 40, wherein the substrate is non-conductive.

47. The method of claim 40, wherein the aerosol spray is directed upwardly.

48. The method of claim 40, wherein the polymeric phase comprises a polymeric solution.

49. The method of claim 40, wherein the polymeric phase comprises a polymeric colloid.

50. The method of claim 40, wherein the polymeric phase comprises a polymeric suspension.

51. The method of claim 40, wherein the liquid precursor further comprises at least one additional phase.

52. The method of claim 40, further comprising the step of:
delivering at least one additional phase into the aerosol spray of the liquid precursor.

53. The method of claim 40, further comprising the step of:
delivering at least one additional phase to the substrate.

54. The method of claim 51, wherein the additional phase comprises a solid phase, preferably the solid phase comprises at least one of particles, fibers or tubes, more preferably the solid phase comprises nanostructures, and even more preferably the solid phase comprises sub-nanostructures.

55. (canceled)

56. (canceled)

57. (canceled)

58. The method of claim 51, wherein the additional phase is delivered as a liquid phase, and preferably such as to transform to a solid phase.

59. The method of claim 51, wherein the additional phase is delivered as a gas phase, and preferably such as to transform to a solid phase.

60. (canceled)

61. The method of claim 51, wherein the additional phase comprises at least one of a polymeric material, a metallic material, a ceramic material, a glass material and a carbon material.

62. The method of claim 51, wherein, in the polymeric film, the additional phase is present as a re-inforcement to the polymeric phase.

63. The method of claim 51, wherein the additional phase comprises one or both of a coloring or fluorescent material.

64. The method of claim 51, wherein the additional phase comprises a cosmetic material, and preferably the cosmetic material comprises one or more essential oils.

65. (canceled)

66. The method of claim 40, wherein the environment is heated such as substantially completely to evaporate the at least one solvent of the polymeric phase prior to the aerosol droplets depositing on the substrate.

67. The method of claim 40, wherein the environment is heated to a temperature which is such as at least partially to melt the polymeric material in the aerosol droplets.

68. The method of claim 67, wherein the environment is heated to a temperature which is such that the polymeric material in the aerosol droplets is molten.

69. The method of claim 40, further comprising the step of:
heating the substrate during deposition.

70. The method of claim 40, further comprising the step of:
pre-heating the substrate prior to deposition.

71. The method of claim 69, wherein the substrate is heated to a temperature below the melting point of the polymeric material in the aerosol droplets.

72. The method of claim 69, wherein the substrate is heated to a temperature above the melting point of the polymeric material in the aerosol droplets, such that a polymeric film is obtained by melt spreading.

73. The method of claim 40, wherein the polymeric film has a thickness of less than about 10 μm.

74. The method of claim 73, wherein the polymeric film has a thickness of less than about 100 nm.

75. The method of claim 40, further comprising the step of:
generating an electrostatic field laterally relative to the substrate, such as electrostatically to guide the aerosol droplets to a surface of the substrate.

76. The apparatus of claim 15, wherein the further delivery unit comprises an aerosol generator.

77. The apparatus of claim 15, wherein the delivery units are disposed in co-axial relation.

78. The apparatus of claim 14, wherein the additional phase comprises a solid phase, preferably the solid phase comprises at least one of particles, fibers or tubes, more preferably the solid phase comprises nanostructures, and even more preferably the solid phase comprises sub-nanostructures.

79. The apparatus of claim 15, wherein the additional phase comprises a solid phase, preferably the solid phase comprises at least one of particles, fibers or tubes, more preferably the solid phase comprises nanostructures, and even more preferably the solid phase comprises sub-nanostructures.

80. The apparatus of claim 14, wherein the additional phase is delivered as a liquid phase, and preferably such as to transform to a solid phase.

81. The apparatus of claim 15, wherein the additional phase is delivered as a liquid phase, and preferably such as to transform to a solid phase.

82. The apparatus of claim 14, wherein the additional phase is delivered as a gas phase, and preferably such as to transform to a solid phase.

83. The apparatus of claim 15, wherein the additional phase is delivered as a gas phase, and preferably such as to transform to a solid phase.

84. The apparatus of claim 14, wherein the additional phase comprises at least one of a polymeric material, a metallic material, a ceramic material, a glass material and a carbon material.

85. The apparatus of claim 15, wherein the additional phase comprises at least one of a polymeric material, a metallic material, a ceramic material, a glass material and a carbon material.

86. The apparatus of claim 14, wherein, in the polymeric film, the additional phase is present as a reinforcement to the polymeric phase.

87. The apparatus of claim 15, wherein the additional phase comprises at least one of a polymeric material, a metallic material, a ceramic material, a glass material and a carbon material.

88. The apparatus of claim 14, wherein the additional phase comprises one or both of a coloring or fluorescent material.

89. The apparatus of claim 15, wherein the additional phase comprises one or both of a coloring or fluorescent material.

90. The apparatus of claim 14, wherein the additional phase comprises a cosmetic material, and preferably the cosmetic material comprises one or more essential oils.

91. The apparatus of claim 15, wherein the additional phase comprises a cosmetic material, and preferably the cosmetic material comprises one or more essential oils.

92. The apparatus of claim 34, wherein the substrate is heated to a temperature below the melting point of the polymeric material in the aerosol droplets.

93. The apparatus of claim 34, wherein the substrate is heated to a temperature above the melting point of the polymeric material in the aerosol droplets, such that a polymeric film is obtained by melt spreading.

94. The method of claim 52, wherein the additional phase comprises a solid phase, preferably the solid phase comprises at least one of particles, fibers or tubes, more preferably the solid phase comprises nanostructures, and even more preferably the solid phase comprises sub-nanostructures.

95. The method of claim 53, wherein the additional phase comprises a solid phase, preferably the solid phase comprises at least one of particles, fibers or tubes, more preferably the solid phase comprises nanostructures, and even more preferably the solid phase comprises sub-nanostructures.

96. The method of claim 52, wherein the additional phase is delivered as a liquid phase, and preferably such as to transform to a solid phase.

97. The method of claim 53, wherein the additional phase is delivered as a liquid phase, and preferably such as to transform to a solid phase.

98. The method of claim 52, wherein the additional phase is delivered as a gas phase, and preferably such as to transform to a solid phase.

99. The method of claim 53, wherein the additional phase is delivered as a gas phase, and preferably such as to transform to a solid phase.

100. The method of claim 52, wherein the additional phase comprises at least one of a polymeric material, a metallic material, a ceramic material, a glass material and a carbon material.

101. The method of claim 53, wherein the additional phase comprises at least one of a polymeric material, a metallic material, a ceramic material, a glass material and a carbon material.

102. The method of claim 52, wherein, in the polymeric film, the additional phase is present as a re-inforcement to the polymeric phase.

103. The method of claim 53, wherein, in the polymeric film, the additional phase is present as a re-inforcement to the polymeric phase.

104. The method of claim 52, wherein the additional phase comprises one or both of a coloring or fluorescent material.

105. The method of claim 53, wherein the additional phase comprises one or both of a coloring or fluorescent material.

106. The method of claim 52, wherein the additional phase comprises a cosmetic material, and preferably the cosmetic material comprises one or more essential oils.

107. The method of claim 53, wherein the additional phase comprises a cosmetic material, and preferably the cosmetic material comprises one or more essential oils.

108. The method of claim 70, wherein the substrate is heated to a temperature below the melting point of the polymeric material in the aerosol droplets.

109. The method of claim 70, wherein the substrate is heated to a temperature above the melting point of the polymeric material in the aerosol droplets, such that a polymeric film is obtained by melt spreading.
